(19) United States
(12) Patent Application Publication
(10) Pub. No.: US 2007/0013572 A1
(43) Pub. Date: Jan. 18, 2007

(54) DEVICE, UNIT AND ARRANGEMENT FOR ONE OR SEVERAL DISTRIBUTED SYSTEMS

(75) Inventor: Lars-Berno Fredriksson, Kinna (SE)

Correspondence Address: CONNOLLY BOVE LODGE & HUTZ LLP, P.O. BOX 2207, WILMINGTON, DE, 19899-2207, US

(73) Assignee: Kvaser Consultant AB, Molndal (SE)

(21) Appl. No.: 11/458,021

(22) Filed: Jul. 17, 2006

Related U.S. Application Data
(63) Continuation of application No. PCT/SE04/01732, filed on Nov. 25, 2004.

(30) Foreign Application Priority Data
Jan. 16, 2004 (SE) 0400074-1

(51) Int. Cl. H03M 1/12

(52) U.S. Cl. 341/156

(57) ABSTRACT

A device collects messages, analog and digital signals from modules (e.g., ECUs, Electronic Controller Units) and sensors arranged on measurement objects in one or more distributed control systems. These systems may work with one or several protocols. The collected information can be of a considerable size, e.g., on the order of one several Gbytes, and can come from CAN or MOST systems arranged on machinery or a vehicle. A commentator system has a recording device for speech and/or image messages and these messages are converted to digital signals which may be distributed to a collection unit along with other signals obtained from the distributed system. Different tasks can be divided up between different experts or actors, and the analysis tasks themselves may be simplified.

### CROSS REFERENCE TO RELATED APPLICATIONS

This application is a continuation under 35 U.S.C. §120 of International Application PCT/SE2004/001732 filed on Nov. 25, 2004. PCT/SE2004/001732 claims priority to SE0400074-1 filed on Jan. 16, 2004. The entire contents of each of these applications is incorporated herein by reference. This application is also related to International Application PCT/SE03/01219, the entire contents of which are incorporated herein by reference.

### BACKGROUND

This disclosure relates to a device for collecting messages, analog and digital signals emanating from modules (so-called ECUs, Electronic Controller Units) and sensors arranged on measurement objects found in one or several distributed control systems, collecting messages, analyzing measurement results and/or controlling and/or monitoring functions and/or structures in a distributed control system that works with a first protocol. The teachings of this disclosure can be utilized, for example, in vehicles such as cars, or machines.

Analysis and monitoring is already known of functions in distributed systems, for example control systems for machines, vehicles, including cars, processes, etc., of the type that are described in patent applications and patents submitted and granted to the same applicant and/or inventor as the present patent application. Reference is made in particular to International Application PCT/SE03/01219, as this disclosure can be considered to be a further development of the subject matter in that application.

Measurement of analog signals and collection of measurement data is carried out and analyzed by special measurement personnel using traditional measurement data collection systems and evaluation programs. This work is separate from the analysis of the communication in the control system. The measurement of the measurement object is usually carried out in an independent environment, for example, the measurement of a car's motor and associated equipment in a test cell.

There is also a need for an arrangement where the functions relating to measurement, control, tools, simulation and protocols can be allocated to different specialists in the respective fields, with the result that the construction of the measurement device, control device, tool and protocol can be kept separate and an implementer does not need to have a thorough knowledge of the specialized field of other implementers, and tools and instruments for special problems can be constructed in a simple way by combining the various functions.

There is also a need in connection with various subsystems of this kind to have an arrangement for reliable and accurate indication of time on which functions in tools, instruments and subsystems are to be based, for example when specialists are to carry out comparative analyses.

There is also a need to be able to divide processor-intensive and memory-intensive tasks relating to calculation, control, measurement, data collection and analysis between the various components involved in an optimal way (c.f. the use of PCs, PDAs, etc.). It is also advantageous in certain situations to be able to utilize unit(s) in or with different functions in the different function stages. There is also a need to be able to combine and relate data from different units within both the same and different measurement systems.

What is needed, then, is a system and method to solve the above problem, and an arrangement that essentially simplifies the work relating to measurement, control, analysis and monitoring and achieves a practical distribution of the functions relating to measurement, control, data collection, tools, simulation, and protocols.

There is also a need to be able to pinpoint in a simple way sporadic noises in the car/machine, sporadic vibrations, etc, in an analysis that is carried out on a large quantity of data. For this purpose, it can be important to be able to integrate voice and/or image information with the large quantity of data signals and to be able to pick out this information from the large quantity of data or relate this information to the large quantity of data in a simple way. When collecting data for later analysis, the source of the problem is often not known. A large quantity of raw data is then collected and markers are inserted manually by an operator when the problem occurs.

### SUMMARY

In one embodiment of this disclosure, markers may be inserted manually by an operator when a problem occurs. In one aspect of this embodiment, this marker may be in the form of a voice message from the operator that is related to the recorded data. For design and use, it is desirable to be able to separate complex and simpler functions and, for example, implement complicated functions and constructions in factories and laboratories and combine these with methods and constructions that require comparatively less expertise and can therefore be carried out on site, by the customer himself, etc.

By means of what is proposed above, among other things, a logging unit can be created with a first connection device that can be connected to the respective distributed system via one or several first transmission or connection channels, with a second connection device that can be connected to one or several voice and/or image generators (commentator systems) via one or several of the first channels, or one or several second transmission or connection channels, with first receiving devices for receiving the first digital signals via the first connection device and with second receiving devices for receiving the second digital signals generated by the respective voice and/or image generator.

In addition, the logging unit can comprise means for coordination of the first and second signals and the provision of sections of the first and second digital signals to the logging unit or display and processing unit comprised in the arrangement which is arranged to effect a comparison function between the information content produced by the respective distributed system during a relevant section of the first digital signals and the information content produced by the voice and/or image generation, concerning the operating or fault situation of the vehicle or machine during a section of the second digital signals that corresponds to or differs from the relevant section of the first signals.

In addition, an arrangement can be obtained comprising a large quantity of first digital signals referring to the operating or fault situations that can be extracted from the respective distributed system, a logging unit that collects the first digital signals via one or several first transmission channels allocated to the first digital signals and arranged between the equipment/vehicle(s) and the logging unit, one or several voice and/or image generators (commentator systems) that are arranged in association with the equipment/vehicle(s) in order to enable a first operator to add supplementary voice and/or image information about operating and/or fault situations in the equipment/vehicle(s) to information content in the first digital signals, where the respective voice and/or image generator comprises or is connected to a conversion device that converts the voice/image to second digital signals, and the logging unit also collects the second digital signals and receives these via a transmission channel or channels that constitute part or parts of the first transmission channel(s) or consist of one or several second transmission channels.

In addition, the arrangement comprises means for coordinating the first and second signals and providing sections of the first and second digital signals to a display or processing unit comprised in the logging unit or in the arrangement, which display or processing unit is arranged to effect a comparison function for the first actor or a second actor between the information content produced by the respective distributed system during a relevant section of the first digital signals and information content produced by voice and/or image generation concerning the operating or fault situation of the vehicle or machine during a section of the second digital signals that corresponds to or differs from the section of the first signals.

In addition, a device can be achieved that can be connected to a commentator system with receiving device for speech and/or image message(s) and with a first device comprised in this or connected to this that converts the speech and/or image message(s) to electrical, preferably digital, signals, where the signals are arranged to be able to be distributed to the collecting unit and this is arranged to incorporate this signal or these signals with signals obtained from the system in the total quantity of information.

In addition, a connection device can be achieved with one or several bus connection units connected or able to be connected to the distributed control system in question and having at least one microprocessor each, which bus connection units are arranged to work with one or several tasks consisting of converting a protocol used on the bus in question to a common protocol used in the basic framework, encapsulation of messages comprised in the target system's protocol in the common protocol, and vice versa, time-stamping of messages and provision of various filter functions and/or trigger functions. At least one second unit that is connected or can be connected to the first unit(s) and is in the form of a coordination unit, coordinates downwards the first units and any additional unit(s) in the case of two or more first units, and where appropriate, in the case of more than one coordination unit, a similar coordination unit with a common time base, and coordinates upwards with a supervisory computer with analysis or diagnosis capacity that is in the system.

An intermediate communication unit may be used for transmission to a remote supervisory computer and, in an alternative embodiment, the coordination unit may be of the type where it works independently without being connected to supervisory computers and carries out logging to a memory, simulations, filtering, etc, where a third unit is connected or can be connected to the coordination unit (804) in form of an information-providing unit. Such an information providing unit may be, for example PC, memory, telephone, where there are short, for example 100-5000 mm, connection leads at least between the target system(s) and the first and second units. A common protocol may be used with messages carried directly, or encapsulated in different protocol(s), wherein the first and second units and the second and third units communicate via the connection leads.

An arrangement for analysis of a vehicle or machine can also be obtained in which a large quantity of first digital signals that relate to the operating or fault situations can be extracted from the respective distributed system. A logging unit collects the first digital signals via one or several first transmission channels allocated to the first digital signals and arranged between the equipment/vehicle(s) and the logging unit, one or more initiation devices can be applied or arranged in connection with the equipment/vehicle(s) in order for a first operator to be able to give an initiation signal associated to an information content in the first digital signals, which initiation signal is related to an operating and/or fault situation in the equipment vehicle(s).

The respective initiation device comprises or is connected to the conversion device that converts the information to one or several second signals, the logging unit also collects the second signal(s) and receives these via a transmission channel or channels which constitute a part or parts of the first transmission channel(s) or consist of one or several second transmission channels, and a device for coordination of the first and second signals provides a section of the first digital signals to a display or processing unit comprised in the logging unit or in the arrangement, which display or processing unit is arranged to effect an indication function for the first actor or a second actor in information content produced by the respective distributed system during comparison of a relevant section of the first digital signals with the second signal(s).

In addition, a device is achieved with a collection unit which is arranged for creating the quantity of information or the part(s) of the quantity of information and also for connecting and receiving operation and/or error messages obtained from one or several distributed systems, for example of the type CAN or MOST, which operation and/or error messages are preferably in the form of digital signals, here called “first signals”, and for connection and reception of speech and/or image message(s) from a commentator system, which speech and/or image message(s) are in the form of “second signals” of the same type as the first signals, and in that the collection unit is arranged, when it receives a signal or signals, to associate the speech and/or image message(s) with the operation and/or error message(s), or vice versa. The association or relating can be carried out to any common detectable reference point or event, for example position, time, noise, spike, etc.

In an additional case, there can be a device with an arrangement for measuring, data transmission, diagnostics and/or analyses via connections and a common basic protocol arranged to work with one or simultaneously with several target systems which communicate using the same or different protocols, and comprising a coordination unit which is connected or can be connected to the control system via first module units, specially adapted for the respective system(s) and tasks in these system(s) and for communication with the coordination unit using the common basic protocol, and with the coordination unit being connected or being able to be connected to and arranged to communicate with second units (811, 813, 815) using the common basic protocol.

It is also possible to achieve a device with an arrangement for measuring, data transmission, diagnostics and/or analyses via connections and a common basic protocol arranged to work with one or simultaneously with several target systems, which communicate using the same or different protocols, and comprising a coordination unit which is connected or can be connected to the control system via first module units, specially adapted for the respective system(s) and tasks in these system(s) and for communication with the coordination unit using the common basic protocol, and with the coordination unit being arranged to be connected to and to communicate with second units using the common basic protocol.

An arrangement with several units can, in addition, be arranged so that the respective units are composed of a first and a second unit part, and the units have first unit parts with constructions corresponding to each other and second unit parts with different constructions.

The tool arrangement or the basic unit can work with information stacks in several layers and is intended to make possible measurements, controls, analysis and/or monitoring of one or several distributed control systems. A complete tool/measurement/control/analysis arrangement stack can logically be divided in general into the following functions:
1. Graphical display function
2. Input/output data function
3. Measurement function
4. Control function
5. Analysis/Simulation/Processing function
6. Database function
7. Protocol function
8. Network connection function.

For very simple protocols, all the functions except 3 and 4 can be carried out within a PC, but usually the functions 7 and 8 are allocated to one or two units that are specially developed for the network protocol that is used in the network that is to be analyzed. The communication between the PC and the special protocol unit is carried out using any protocol and connection that is standardized for general exchange of data between the PC and its peripherals, for example PCMCIA, vV24, USB, etc. This communication only transfers data and the characteristics of the utilized protocol are not used as the basis for the analysis/processing work or for the characteristics of the database.

The measurement function and the control function are usually separated, particularly during the development work. When the development work has been completed, the measurement functions are reduced as much as possible and combined in a control unit, for example for motor control or gearbox control, that is connected to the distributed control system. In order to solve the abovementioned problems, the architecture is expanded as follows for a first network protocol (that can be generic or special) to which the following are connected, adapted for a second protocol:
1. Gateway function
2. Measurement/Control/Analysis/Processing function
3. Database interface function
4. Protocol function
5. Network connection function.

Thus two or more units can be connected consecutively in series between the tool and the control system, with one of the units being connected directly or via an additional unit or units to the target system (the control system). The tool arrangement can be arranged so that first units are arranged to handle information in an upper layer in the stack, that is general information, while the second unit is arranged to handle information in a layer beneath the upper layer in the stack, that is information of a special nature for the target system.

The second units can be arranged to handle information in a layer below the last-mentioned layer in the stack. The tool arrangement can be arranged to work with a protocol allocated to it, and information about differences between the functions related to information in the stack associated with the unit connected to the control system and the control system's actual functions can be transferred to the tool arrangement for reading or controlling the information by means of the allocated protocol.

A gateway function or protocol converter can transform information in a protocol utilized by the control system to information in the allocated protocol, or vice versa. The gateway unit can be connected to the PC or the PDA via a standard protocol, for example USB, and can also be connected to second units connected to the system via a variant of the same standard protocol enhanced with a time-synchronization function that enables all the units connected to the gateway to work with or in relation to a common time base.

### BRIEF DESCRIPTION OF THE DRAWINGS

Embodiments of this disclosure will be described below with reference to the attached drawings in which:

FIG. 1 shows in block diagram form and in outline, the connection of the tools and units to the control system and a measurement system;

FIG. 2 shows in block diagram form and in outline, parts of FIG. 1 supplemented with additional parts;

FIG. 3 shows in block diagram form, a measurement arrangement for a turbo unit as an example of the measurement part of the invention;

FIG. 4 shows in block diagram form, a construction of a first and a second unit;

FIG. 5 shows in block diagram form, a measurement, analysis and simulation arrangement in a control system;

FIGS. 6 and 7 show in block diagram form, additional embodiments in relation to the embodiment according to FIGS. 1-5;

FIG. 8 shows in block diagram form and in outline side views, function parts and units parts that can be coordinated; and

FIG. 9 shows an outline drawing of information handling.

### DETAILED DESCRIPTION

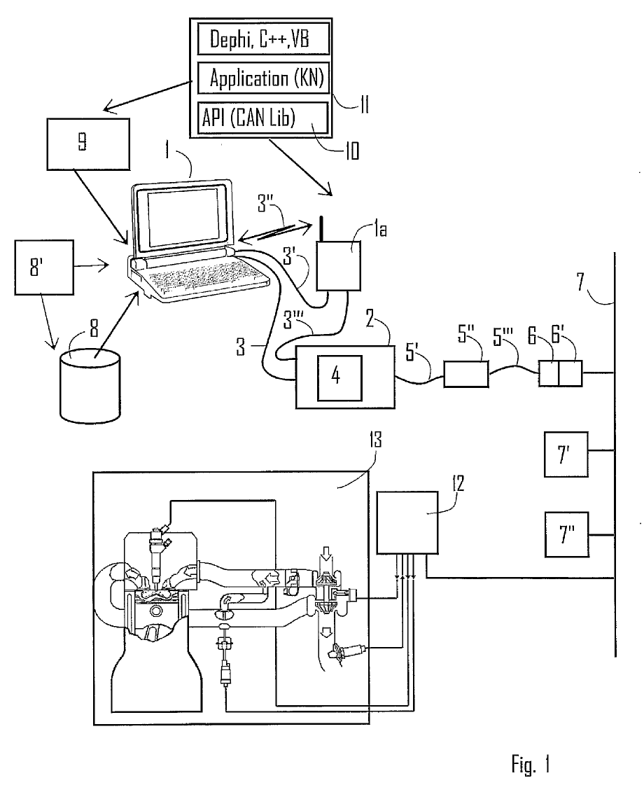

The tool or the tool arrangement includes of a number of modules or units that are shown schematically in FIG. 1, where the unit 1, the basic unit, comprises a unit suitable for communication with people and with associated equipment, for example a PC or PDA of conventional type. In an embodiment, unit 2 is connected to unit 1, in which unit 2 includes a PC interface. The connection is carried out via a connection 3 which can be of a currently-available type for connecting peripherals to a PC, for example USB, FireWire, PCI, Bluetooth, etc.

Unit 2 comprises a microprocessor with the requisite peripherals, symbolized by 4, and a bus module that comprises a first cable part 5′, a bus adapter unit 5″, and a second cable part 5′″ that terminates in a connector 6 by which it is connected to the system bus 7 via the connector 6′ attached to the bus. System modules connected to the system are symbolized by 7′, 7″, and 12.

The basic unit 1 contains a database 8 which is suitable for the purpose, an application 9 working with the database, and an application interface (API) 10 working with the unit 2. Using the database editor 8′, the user can edit the database and specify how the values in this are to be interpreted and represented on the display screen in the tool. The entry of interpretation data can be carried out directly from the PC's keyboard or from a configuration file. An example of a database editor is “Navigator Database Editor” Kvaser AB, Sweden.

The application may be written in a commonly-used language, for example Delphi, C++ or Visual Basic. An example of an application is Kvaser Navigator and an example of an API is CANlib from Kvaser AB. The construction is shown schematically by 11. An example of the unit 2 is LAPcan II and a unit 5″ includes DRVcan 251, these also from Kvaser AB.

Using the described arrangement and exemplified products, the system 7 can be analyzed and can work with the protocol CAN and a physical interface according to the specification for Philips CANdriver 82C251. A unit in the system 7 can be a motor control unit 12, for example Bosch DI-Motronic, which controls the motor 13.

A modern PC has sufficient processing power and memory to hold a complex database and to carry out processor-intensive calculation and analysis tasks. In this respect, a PDA is more limited, for which reason it can be expedient to allocate processor- intensive and memory-intensive tasks to the unit 2 and/or reduce the capacity of the tool in a PDA version. This can, for example, be carried out by utilizing the PC version as a “programming tool” for the PDA version. Special measurement and analysis arrangements and parts of the database necessary for these and one or several fixed display arrangements of measurement and analysis results on the screen of the PDA. After it has been determined in the PC which tasks are to be resolved and how the results are to be displayed, a configuration file is generated which is then downloaded to the PDA. The configuration can be carried out in steps, for example with a separate configuration of the display function, another for the database function, for example.

The unit 2 according to FIG. 1 can thus alternatively comprise a PDA unit la with connections 3′, 3″, and 3′″ to the tool part 1 (3′=fixed and 3″=wireless) and the unit 2 respectively, which, as described below, can form a first unit, with the PDA unit being considered to be comprised in a tool arrangement with the unit 1.

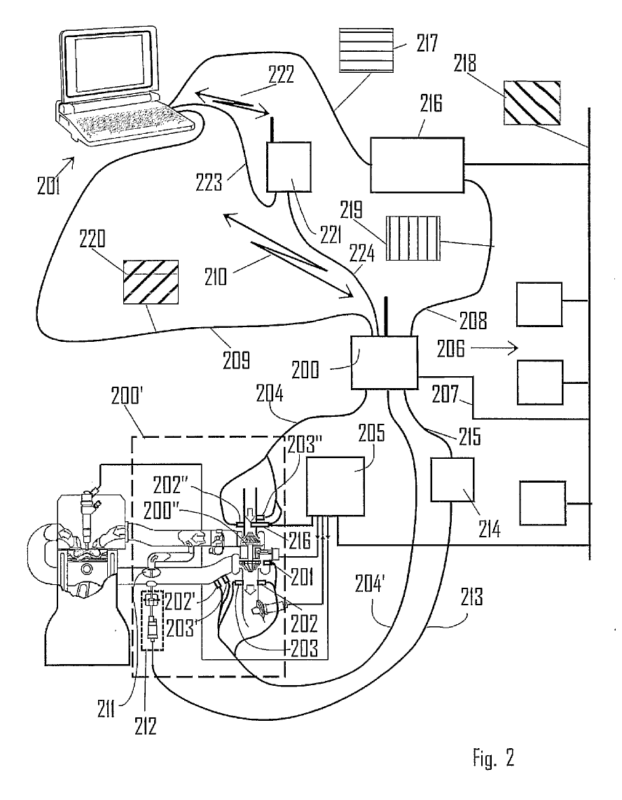

A solution according to the invention is shown in FIG. 2. A measurement module 200 is introduced here for measuring the turbo unit 2001. A number of detectors are connected to this by cabling 204 and 204′, such as sensors of various kinds, for example a velocity sensor 201, a number of pressure sensors 202, 202′, 202″, and a number of temperature sensors 203, 203′, and 203″ and a flow meter 216, for measuring the speed of the compressor/turbine unit 200″, incoming and outgoing pressure and temperature, ingoing flow, etc, using which the characteristics of the turbo (the measurement object) can be calculated. The measurement module 200 filters, collects, time-stamps and processes the measurement signals in a suitable way and places them in a local database, all in accordance with the rules of the database.

Supplementary measurements that are carried out by the motor control unit 205 can be read from the CAN bus system 206 via the connection 207, either by listening to the CAN bus for messages with measurement values that the motor control module normally transmits, or in response to a request from the measurement module. The request can be carried out according to CCP (CAN Calibration Protocol). The measurement module then sends the measurement results to the PC for further processing. The measurement results can be sent either via the CAN bus in the system 206, via the exclusive CAN connection 208, via the USB connection 209 or via the Bluetooth connection 210. The character and arrangement of the measurements determine which path is suitable for the transmission of the measurement values. For more complex measurements in a test cell, it can be appropriate to have a dedicated PC for the measurement value analysis and to have transmission via USB, while in a test car it is possible to carry out simpler measurements and to transmit measurement values to a PDA via the car's ordinary CAN bus.

In certain cases, it can be appropriate to let the measurement module be a control device and to let the measurement module carry out control of functions carried out by control devices such as stepping devices, electric motors, etc. FIG. 2 shows how the waste gate valve 211 is controlled by the stepping device 212 which is connected to the amplifier unit 214 by the connection 213. The amplifier unit obtains an analogue or digital control signal from the measurement unit 200 via the connection 215. The measurement unit obtains control commands from the PC which are converted to a control signal which is amplified by the amplifier 214, the output signal from which is converted to a opening position of the valve 211 which is effected by the stepping device 212. As an alternative to the PC giving control commands, a regulating algorithm can be inserted in the measurement unit, so that the valve position is controlled by feedback from appropriate measurement signals.

The tool according to FIG. 2 thus consists of a basic unit 201 and a unit 216 that converts the low-level protocol, for example CAN, of the measurement system 206 to a standard protocol for PC, for example PCMCIA or USB as described above. A unit 200 is connected to the unit 216, which unit 200 is connected in turn to the system 206 and to the sensors on the measurement object 2001. The communication between the unit 201 and the unit 216 is carried out using a first protocol symbolized by 217, communication between the unit 216 and the system 206 is carried out using a second system protocol 218, and communication between the unit 216 and the unit 200 is carried out using a third protocol symbolized by 219. The communication between the unit 200 and 201 is carried out using a fourth protocol 220.

The term protocol means here a basic protocol including bit transmission plus higher layers. These layers are not the same as those of the currently-used OSI model.

Many tasks that, according to the OSI model, are handled by the lower layers, can be carried out by higher layers. For example, the protocol 217 can be based on PCMCIA supplemented by API functions that are tailor-made for a particular unit 216 and the protocol 220 can be based on a suitable variant of USB, for example USB Highspeed, USB Fullspeed or USB Lowspeed, supplemented by API functions that are tailor-made for the unit 200. By variant of a protocol is thus meant such larger or smaller changes. These modifications can be completely defined or can be modified by a modifying protocol.

As a comparison, J1939 can be mentioned as an example of a completely-defined protocol based on the basic protocol CAN, and CanKingdom can be mentioned as an example of a protocol that can be modified and that is also based on CAN, using which a final protocol can be defined in detail. Corresponding principles can be applied for general basic protocols such as USB, TCP/IP, etc., in order to obtain suitable protocols for communication between the tool and its interface with the target system. There can be additional protocols, specially adapted to be used in a configuration or start-up phase. The tools known to date have limitations caused by their architecture.

To date, systems have been constructed using the approach that the communication protocol is a part that is as independent of the applications of possible. As the description shows, the invention operates with several protocols, also including APIs and with details in the communication protocol such as bit transmission being modified to suit the applications and with the structure and rules of the database being common regardless of which basic protocol is used for the communication. The data structures of the system protocol are used throughout. For example, if the system protocol is J1939, PGAs and SPNs are used in accordance with J1939-71, even if the communication protocol is USB or Bluetooth.

For analysis of events and measurements in systems of the type described, it is important to be able to relate these temporally. In the solution according to the invention that is shown in FIG. 2, this can be carried out in a simple way for the measurements carried out by the unit 200 using a clock function in this unit. Measurement values from 205 can be roughly related to the measurement values in 200 by time- stamping in the unit 200 suitably-selected messages received from the system 206. Some of these selected messages can contain measurement values or events that are transmitted as standard in the system 206. The quality depends, however, upon how well the time delay between the measurement and the transmission of the respective measurement signal in the system 206 is known.

An alternative is to connect the units 200 and 205 to one and the same sensor, for example the flow meter 216. The measurement signals from the two units can be related to each other temporally in the PC by correlating the flow values between the respective units, as they are based on a common sensor. The tool arrangement can comprise a complex part 201 and a less complex part (PDA) 221. The connections 209, 222, 223, 224 are arranged in a corresponding way to 3, 3′, 3″, and 3′″.

In the example above, it has been assumed that the turbo system only contains one turbo. Today, however, the trend is towards more complex double or triple systems in which any turbo can be electrically-assisted or driven completely by electricity. Several such solutions are described in the technical literature, for example articles issued by 3K-Warner Turbosystems GmbH in the series Academy (http://www.turbos.bwauto.com/): “Regulated Two-Stage Turbocharging-3k-Warner's New Charging System for Commercial Diesel Engines” by graduate engineer Frank Pflüger, “Der eBooster” by Dr. S. Münz et. al. and “Moderne Aufladekonzepte fur PKW-Dieselmotoren” by P. Hoecker et al. Such systems require considerably more measurements than a measurement unit 200 can carry out.

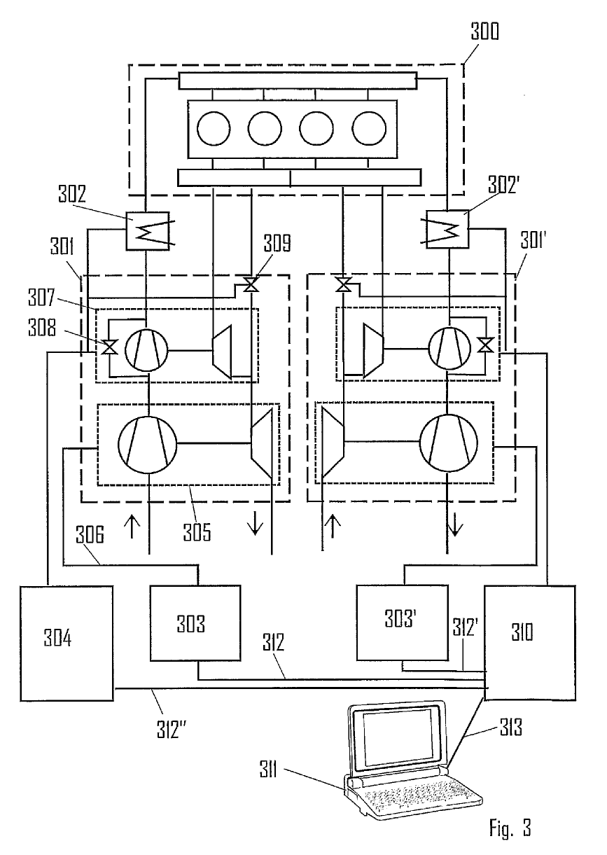

The solution to this problem is to connect together several measurement units to one or several shared buses. Each measurement unit measures and, if required, also regulates one turbo in the multi-turbo system. The clocks in each measurement unit are synchronized or set in relation to each other via one of the buses so that a common time base is obtained which can be used to coordinate measurement values and required values temporally. An embodiment of a distributed measurement system with the units 303, 303′, 304 and 310 is shown in FIG. 3. Two identical two-stage turbo units 301 and 3011 that supply the motor with compressed air via the coolers 302 and 302′ are connected to a combustion motor 300. There are two types of measurement module. A simple measurement module, 303, with a measuring part, a processor, a CAN bus connection and a USB connection.

Such a unit can perform measurement and regulating tasks for one turbo. The more complex unit 304 has, in addition, also an additional processor with several network connections, for example Bluetooth connection, USB connections, or several CAN connections or combinations of these, using which a measurement system network can be constructed from one complex unit together with one or several simple and/or complex units. The simpler unit 303 is connected to the low-pressure turbo 305 via connecting cabling 306 which, in turn, is connected to requisite sensors for carrying out the measurement as shown in the example above. The unit 304 is connected to the high-pressure turbo 307 and also to the intercooler 302 for measurements. In addition, it regulates the bypass valve 308 and the exhaust gas distributing valve 309.

In the same way, the identical turbo system 301′ is connected to the measurement units 303′ and 310. The measurement module 310 is of the same type as 304, but has here, in addition, an interconnecting function between the various measurement modules and the PC. USB has been selected as the common message transmission protocol. The measurement module 310 is connected to the measurement modules 303, 303′, and 304 by the connections 312, 312′ and 312″ respectively and to the PC by the connection 313.

In its simplest form, 310 has the function of a USB hub and compiling of the measurement values for analysis is then carried out by the PC. The measurement system's USB network differs from a standard network in that the USB protocol between the measurement units has an additional feature, by means of which a common time is obtained in the measurement system. The measurement module 310 has, however, the capacity to execute complex programs that take some of the load off the PC. This is particularly valuable if the PC is replaced by a unit with lower performance, for example a PDA, or if the system is to be used for independent compiling of measurement values where all the calculation can be carried out by the units involved and stored in the memories of the complex measurement units.

General modules of the type 303 and 304 can thus be modified in the simple way by means of instructions for special tasks and measurement configurations which are thereby standardized, which simplifies both the taking of the measurements and the interpretation of the measurement results. Many small measurement systems are connected together and form larger systems. As a result of the simplicity of the small systems, engineers with the task of creating models of machines, who have expertise in simulation but limited knowledge of taking measurements, are able to set up the measurement arrangements so that they provide information about the quality of the simulation models in an optimal way. The measurement arrangements for subsystems can thus be integrated into larger measurement arrangements with other objectives in a simple way and without causing interference. In this way, measurements for completely different tasks can be utilized for verifying models. For example, a measurement for providing information about a motor's cooling system or electrical system can be utilized for verifying models of the turbo system.

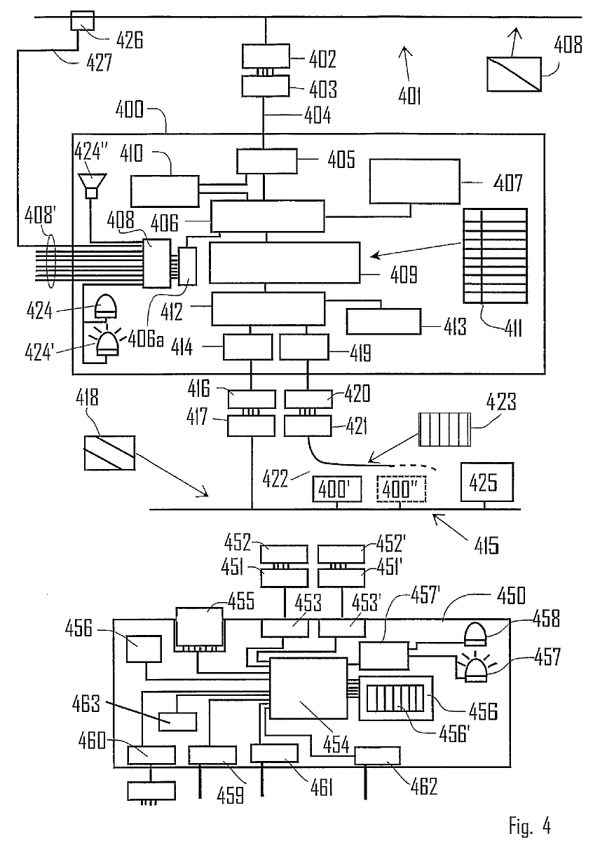

FIG. 4 shows schematically the construction of a unit 303 according to FIG. 3, here designated 400. For the sake of clarity, it is provided with two microprocessors, but the task can be carried out using one microprocessor. The unit 400 is connected on one side to a system 401 via the connections 402, 403 and the connection lead 404. The signals on the bus can be read by the microprocessor 406 via the adapter electronics 405. By means of instructions stored in the memory 407, the signals can be interpreted in accordance with the protocol 408 utilized in the system. In its simplest form, the interpretation can involve only the transference of the received bit pattern, but the interpretation can be of an extensive type where much additional information specified by the protocol's rules is supplied by the microprocessor.

Application software, that is instructions for one or several applications that process information available to the microprocessor, is also stored in the memory 407, symbolized by 4071. The information interpreted in this way is transferred to the two-port memory 409.

Additional information of interest can be added to the interpreted information, for example time-stamping when the information was received from the system. The time is obtained from the clock 410 which is triggered in a suitable way by the adapter electronics, for example at the start of the reception of a message. The information is stored in the two-port memory in an organized way according to rules modified in accordance with the requirements of the system protocol, so that specific information is stored in a specific location indicated by the table 411. The two-port memory 409 can be read by the microprocessor 412 that can communicate according to a second protocol using rules stored in the memory 413 and can communicate physically with a second system 415 via the adapter electronics 414 via the connectors 416 and 417. Rules are also stored in the memory 413 for how the information stored in 409 according to the rules in 407 and 411 is converted according to the rules for the second protocol 418.

In simpler systems, the second protocol can be based on CAN and several units 400′, 400″, etc., of the type 400, and can connect a unit 425 of the type 201 or 221 in the way described above. The second protocol is thus modified for communication between units comprised in a measurement system or analysis system. In this way, a separate measurement system and/or analysis system can be created in simple way, in which data, information and commands are exchanged using a protocol that is common to the system and that is independent of the target system's protocol.

The unit 400 contains a part in the microprocessor arrangement 406, shown as 406a (I/O), that works with digital and/or analog functions. The part 406a comprises inputs and/or outputs to the multiplex and amplifier part 408 which in turn is connected to the cabling 408′ for the functions. The amplifier part 408 can contain electronics for serving temperature sensors, for example K-elements. In the same way as described above, the unit 400 also contains rules for a third protocol with adapter unit 419 and connectors 420 and 421 which are connected to the connection 422 using the protocol 423. A suitable protocol can be based on USB. The unit 400 can have a simple human interface in the form of light-emitting diodes 424, 424′, loudspeaker devices 424″, etc., for indicating voltage supply, communication, diverse faults, etc.

A more complex unit can consist of a module such as 400 that is connected via a suitable connection, for example a USE connection, to a unit 450 with a microprocessor with peripherals specially adapted to handle communication and calculation problems. Such an arrangement has many advantages. The analog and strictly realtime-related problems are solved by the module 400, while the processor-intensive and less realtime-critical tasks are carried out by the unit 450. This unit is well-suited to request information which is available from the target system, both information according to CCP or a similar calibration protocol, and diagnostic information in accordance with ISO 15765 or a similar protocol, as these are created to be handled at a higher non-realtime-critical level.

As far as construction is concerned, there is a great difference between the two units, which require different skills and experience on the part of the designers. By means of the USB connection and the associated protocol, a well-defined interface is obtained between the modules which facilitates a parallel and largely independent development of the two units. In addition, the units can be manufactured as separate units, but can also be simply designed as one unit with an internal USB communication, either on one and the same PCB or as a sandwich construction. The module 450 is connected directly to one or several modules 400 by connectors that are shown by 451, 452, 451′, 452′ etc., for example by a USB-based connection.

Communication circuits 453, 453′ are connected to a microprocessor 454 with associated peripherals, including memory or memories. These memories contain application software, that is instructions for one or several applications that process information available to the microprocessor. A memory card 455 is arranged for logging, recording and playback facilities, etc. A memory 456 connected to the microprocessor can be written to and read from two (both) directions, that is from the system side and the tool side. The memory can be divided into a number of sub-memories with different algorithms 456′, that are protected by passwords. The content can also be encrypted.

Verifications and signaling are protected by codes, passwords, etc. The function can comprise encryption according to PGP (Pretty Good Privacy). The clock 456 can be synchronized or coordinated with the clock 410 in the first unit via the protocol or by a separate clock- synchronization link. For examples of synchronization via protocols, refer to CanKingdom or TTCAN (ISO 11898-4). In this way, all first units connected to a second unit can be time-synchronized. In the same way, the second units can be time-synchronized with each other.

By means of the time synchronization of the different units, the execution of the applications in the different units can be synchronized or related to each other temporally. In this way, execution of applications or application parts that correspond to measurements can be coordinated with execution of applications or application parts that are responsible for communication within and between the different units. This means, among other things, that messages sent according to an event-driven protocol, for example CAN, can appear in a time-controlled way, as applications for the transmission of messages are executed with temporal coordination. As a result of the execution of applications for measurements being coordinated with the transmission of measurement results, a temporal relationship is obtained between the measurement and the distribution of the measurement result in the system in the form of messages. The same can, of course, apply for indicated events and messages with information concerning the respective event.

Utilizing suitable software, the unit 450 can, together with the unit 400, simulate completely or partially an ECU in an ordinary CAN system in a vehicle. The unit 450 can be programmed for testing of various kinds. In the event of approval of the test, a device (lamp, bell, loudspeaker, etc) 457 is activated, via an adapter unit 457′, if required. If the equipment and the test function programmed therein receive a negative indication to the effect that the vehicle/car (the object) does not fulfill the requirements made of it, the device 458 is activated.

The devices 457, 458 can consist of a device that operates with different colors, signals, etc., see above. The unit 450 can be equipped with devices for communication with other network protocols, for example Bluetooth 459 and TCP/IP 460 for communication between a network of units 450 and/or the tool unit implemented in the PC or PDA. As an alternative to disk storage, so-called USB memory sticks can be connected via a USB connection. For communication over a telecommunication network, the unit can be equipped with a GSM module 461 and for time synchronization or clock synchronization the unit can be equipped with a GPS module 462 which can also be used for position determination.

A random number generator 463 which generates random numbers for code functions, etc, is also connected to the microprocessor 454. See the above, regarding the protocol. The user can specify that what is to be sent is to go to special tools identified by ID, for example KVASER's ID, where KVASER provides the relevant ID. The equipment can be arranged to work with hardcoded serial numbers and ID, to ensure that the correct pieces of equipment obtain the correct settings. For this purpose, there is a memory area that can be written to and read from the PC. Customer numbers can be utilized for the system and the PC. Verifications and signatures are arranged to be carried out utilizing hardcoded keys. The PDA unit can be replaced by a simpler unit with the functions for approval and non-approval, that is the unit has communication with the user that is even more limited than that of the PDA. The powerful PC part can be consulted or can take over the testing in the event of a non-approved result. In one embodiment, the PDA unit can solve only known problems.

Interactions can be carried out by data and/or voice. Problems that are not resolved at PDA level are resolved at PC level and entered in the database, whereby the problem and its solution become known and can thereafter, for example, be included in those that can be resolved by the PDA or the unit in question.

Signaling and verification can be carried out using asymmetric encryption, both between the PC and PDA and between the PDA and vehicles/cars (objects) in order to ensure that unauthorized manipulation of objects is made difficult and to ensure that it is possible to be able to trace later how the manipulation has been carried out. Hardcoded ID and digital signatures are thus utilized, in order to ensure that unauthorized or unintentional manipulation is prevented or made difficult and also to ensure that the manipulations that have been carried out can be traced and to ensure that different users of one and the same tool can be distinguished and can have access to different data and utilization options.

Traditionally, analog and digital measurements are separated from the communication in a network. In addition, the measurement system is divided into modules according to the type of measurement. A measurement unit can be constructed of a communication module, one or several temperature measurement modules, one or several analogue modules, etc. The communication module is used for communicating measurement values.

The modules 400 described in this disclosure have the capacity to carry out all types of measurement and to participate in the measurement object's network communication. Analog measurements can also be carried out on the network with the connector 426 via the cable 427 and correlated to messages appearing on the bus. In this way, one and the same module 400 can be used for input data for tools for both analysis of network communication and for analysis of physical events in a target system and also for simulation of modules.

Measurement values are normally presented as a function of time. In connection with a turbo, however, the measurement values are often required to be compared with the relevant state in the map associated with the compressor or turbine. This is particularly valuable during test running. A unit 450 has the capacity to process the information so that the result can be presented as an operation point in a compressor or turbine map. The test driver can see on his PC or PDA in real time where the operation point in question lies in relation to the compressor map in question. By means of commands from his PDA, he can initiate logging of measurement values when the operation point lies in an area that is of interest for the development. The unit 450 can also be given trigger conditions for logging data, so that this is only carried out at points of interest, which greatly reduces the memory required for logging and simplifies later analysis Other trigger conditions of interest can be set up, for example in the event of noises, high or low temperatures, etc. The unit 450 is particularly suitable for special programming, as time-critical and complicated measurement is carried out by the unit 400, and the connection 422 that utilizes the protocol 423 constitutes an effective and well-defined interface>between the two tasks. This can, for example, be based on USB Highspeed.

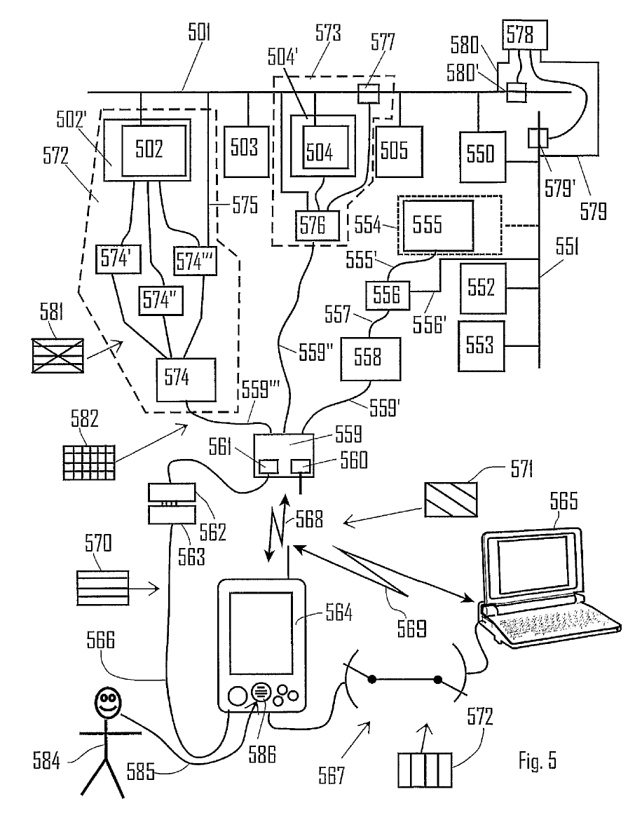

FIG. 5 shows schematically an example of a measurement arrangement. The target system consists of two communication buses 501 and 551 that are connected via a gateway 550. A number of units 502,503, 504 and 505, and 552 and 553 respectively are connected to the buses. A module 554 is to be developed to be included in the system and to be connected to the bus 551. The requisite input data is available in the unit 555, which is connected by the cabling 555′ to the first unit 556 which corresponds to a measurement module 400.

The first unit 556 is connected to the second unit 558, which corresponds to a module 450, via the USB connection 557, modified for time synchronization of the measurement system. The unit 556 is connected to the bus 551 by the connection 556′. The units 556 and 558 together simulate the module 554 in the system. The unit 558 is connected to the system coordination unit 559 of the type 550 via the USB connection 559′, which is also modified for time synchronization. The bit transmission in the USB connections 557 and 559′ can be different and the communication protocols are then considered to be different variants even though they differ only in bit transmission.

The system synchronization unit 559 can be connected to a tool in various ways. Communication circuits for Bluetooth and USB (for example) are indicated by 560,561. Connectors 562,563 make possible the connection of a simplified tool part 564 (PDA) and a complex tool part 565, which parts can also be connected to the circuit 560 in the case of Bluetooth. The connections 566,567, 568,569 can be wired or wireless. A PDA 564 can thus have a wireless connection to the circuit 560 (see 568) and the part 565 (see 569). A protocol 570 can be based on USB and a protocol 571 is based on Bluetooth. A protocol 572 can be based on TCP/IP (Ethernet) for communication on the Internet (LAN) or on the World Wide Web. The module 559 also coordinates the subsystems 572 and 573. The measurement subsystem 572 measures the object 502′ for the network module 502.

The measurement comprises three different parts in the object 502′ that are served by the measurement modules 574′, 547″, and 574′″ of the type 400, which in turn are connected to the coordination sub-module 574 communicating using the protocol 58 1. The measurement module 574′″ is connected to the system bus 501 via the connection 575. The measurement subsystem 572 can thereby not only coordinate the measurements with the bus traffic but can also leave information about it and analyze that information. The module 574 communicates with the coordination module 559 using the protocol 582. The measurement object 504′ in the measurement subsystem 573 is served only by the measurement module 576 which is directly connected to the module 559. The module 576 is also connected to the bus 501 and, in addition, is connected to it by the connection device 577 for the taking of measurements. The module 576 can thereby carry out detailed analog analyses of the message signals on the network.

An additional variant of the use of modules of type 400 (or alternatively, 400+450) is shown by the module 578 which has an analogue connection to the two buses by 579 and 580 respectively, and is connected for communication by 579′ and 580′ respectively. By means of this connection, a detailed analysis of both the digital and analogue communication sequences can be carried out on the respective buses individually and in combination over the gateway 550. The result of the analysis can be communicated over either bus to the measurement system or, in the alternative with the combined module 400+450, can be stored in the memory of the 450 part.

The unit 559 is thus the hub in a complex measurement and analysis system that can work independently or in combination with second units in a tool system. As each unit in the measurement system comprises one or several microprocessors, some optimized for measurement and analysis, specialized for certain tasks with stringent realtime requirements, others optimized for demanding calculation tasks and logging of results and data, a total measurement and analysis system is obtained which has a very large capacity but which can be reconfigured and maintained in a simple way using high-level standard units adapted for communication with and presentation of results to people, such as a PC or PDA, directly or via a general communication system. Both problems relating to communication and problems relating to measurement can be analyzed and solved.

Solutions, tests, diagnostics and simulations can be input into the system and the system provides facilities for serving and being served in parallel by many people with different specialties in a reliable way. As described above, the various parts of the tool can communicate with each other using different protocols and protocol variants. Depending upon the nature of the task that the tool is to solve, different demands are made of the protocols. In the parts that are close to the target system, real-time requirements and time-stamping of messages and events are important, for which reason protocol variants with time- synchronization characteristics are preferably used.

For purely analytical tasks, realtime characteristics are less important, for which reason standard protocols are advantageously utilized as the basis. If there is a need for wireless communication or communication over a general communication network, variants of commonly-used communication protocols are used, such as Bluetooth, TCP/IP, GSM, etc. By this means, it is attempted as far as possible to retain the organization and construction of signals and commands that are found in the protocol of the target system, and to break them up into their components as late as possible. For example, structures with SPNs and PGNs in a target system of the J1939 type are retained until the information is processed in the tool part residing in a PC or PDA.

In many cases, a fault or an event arises for which it is difficult to determine the cause, for example sporadic noises in a car, sporadic vibrations, etc. It can then be expedient to log as much data is possible and let the operator indicate when the fault or event occurs. This can be carried out in a simple way by the operator generating a signal, for example by pressing a button, which can be detected by the system and generate a marker in the collected data. The subsequent analysis work can then be concentrated on data that was collected around the time of the appearance of the marker.

A more complex method is for the system to introduce a channel for voice-recording which can be related temporally to other recorded data. When the problem occurs, the operator 584 utters a voice message 585 which is recorded by the microphone 586 in the unit 564, that is a simple commentator system. As soon as the unit 564 commences a sound recording, it sends a signal 587 via the connection 566 which is recorded and time-stamped as a voice event in the unit 559. The unit 564 records the sound from the operator 584 and transfers it in digital form to the unit 559 which saves it in a suitable way, for example as a voice file. As the subsystems connected to 559 are synchronized in time with 559, and hence also with each other, the information from the operator can now be related to all the data collected in the system. In addition, the unit 559 can download the voice information to connected parts via the connections 559′, 559″, and 559′″.

Image and sound have three different functions in relation to data from the first signals/connections.

1. Add information by visualizing via image and commentating via sound. This information assists the other persons who are to analyze and interpret the first signals.

2. Sound and image can also be used to identify first signals, in that the first person can describe the measurement and the conditions surrounding the measurement that are not apparent from the first signals or are difficult to interpret from the first signals, for example noises, or characteristics during the measurement, such as high altitude, thunderstorm, sharp bend, etc.

3. Image and, in particular, sound can be used to initiate the measurement by means of the intensity of the sound or by detection of different commands in a similar way to the way “hands-free” operation associates different sound images/words with different functions.

Point 3 is quite easy to distinguish when applicable, but a well-chosen word with function 3 can also provide a function that can be related to 1 and 2, depending upon how the word is interpreted and used.

Triggering is currently carried out by means of conditions that are laid down for signals that are obtained from one or two first connections. At least one of these two connections can be based on analogue signals in the system that are converted to digital signals, by means of any one of the units of type 400, internal or external to the unit. This can also apply in a system with this as the only trigger, where the other signals are only used for the function 1 and/or 2 as above. In this case, it can be appropriate to utilize the second unit for indication by visual means (for example, light-emitting diodes or marking on a computer screen) or via an audio output to a unit with a loudspeaker. It is also possible to identify and describe what caused the triggering via different images, audio as well as visual, for example “the temperature is too high”, or “error message detected”.

An advantage of sound images is that the operator can give and receive this information without interrupting the activity that is being carried out, for example driving the car. An advantage of visual images is that it is possible to obtain in a simple way high-resolution detailed information about locations in space and time that can be related to other information of the same type with lower resolution.

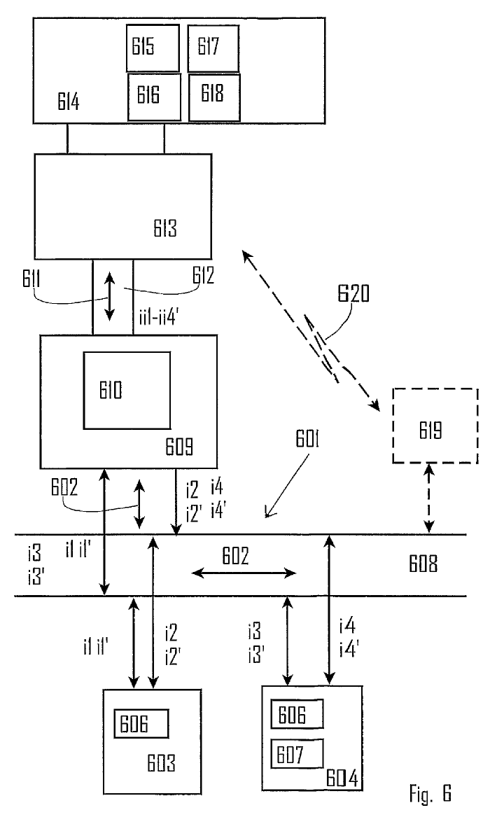

An additional embodiment is shown in FIG. 6. A distributed control system, measurement system or data collection system 601 works with a first protocol 602 and comprises a number of modules 603 and 604 for various tasks. For example, the module 603 is arranged to carry out temperature measurements using the sensor 606, while the module 604 can carry out several tasks 606,607, which can be selected by commands. Commands i1, i3 and command responses i1′, i3′ and signals i2, i4, and signal responses i2′, i4′ are exchanged using the first protocol via the connection 608. A first unit 609, arranged for communication with the system and at least certain analysis of the same using the first protocol, is connected to the connection and can exchange signals and commands i1, i1′, i2, i2′, i3, i3′ with a first structure and function arranged in accordance with the requirements of the system and the first protocol.

The first unit comprises a conversion unit 610 that can convert signals and commands of a first structure and function according to the requirements of the first protocol and the system to a second structure and function adapted to a system, actual or virtual, working with a second protocol 611 with similar requirements. The converted signals and commands, marked in the figure by ii1-ii4′, are transmitted completely or partially via the connection 612 to a second unit 613 arranged to work with the second protocol and to forward these in more or less processed form to the tool 614.

The tool 614 is arranged to work with the second protocol and the system, with properties such as scanning of messages 615, control functions 616, analysis functions 617 and structure functions 618. The described flow can take place in the opposite direction, from the tool to the first system, with signals and commands generated for the second system and the protocol being sent via the second unit to the first unit where the signals and commands are converted to a structure and function according to the requirements of the first system and the first protocol.

The utilization of a second module 619 in the system as a gateway for the communication between the first unit and the tool is also within the concept of this disclosure. In a vehicle, a suitable such module can be a module for telephone communication between the vehicle and the general telecommunication network, or a module for statutory diagnostic information, so-called “OnBoard Diagnostics” (OBD), and a suitable second protocol can then be a standardized diagnostics protocol, for example a variant of KWP 2000 for CAN (ISO 15765).

By variant of the protocol KWP is meant, for example, an implementation of the standard that is specific to a make of car. The unit (PDA or the like) or second part that can be connected to the computer or the first part (PC) is capable of carrying out some of the tasks that the PC can carry out. These tasks are set up in the PC and downloaded to the PDA in configuration files.

The PDA or like can consist of a standard unit that does not have the interface in question, for example a CAN interface. The PDA can be replaced by a simpler unit with indications, for example a lamp, lamps, signaling devices, etc, that indicate whether the system tested, simulated, etc, by the unit fulfils predetermined functions or specifications. The PDA or the unit has limited communication with the user and, in this way, simplified procedures can be utilized for testing or the like. If the PDA (Personal Digital Assistant) or the unit emits a signal to the effect that the test or the like cannot be carried out, it can be connected to the more powerful PC that can download additional or other tasks to the PDA, for example after it has carried out analysis, simulation, etc, of the received information. The PDA or the like can also be disconnected from the PC by means of a special disconnection device (not shown) after the download and can be utilized for other systems than those shown. Several PDAs can be loaded from the PC and distributed to various technicians in the field.

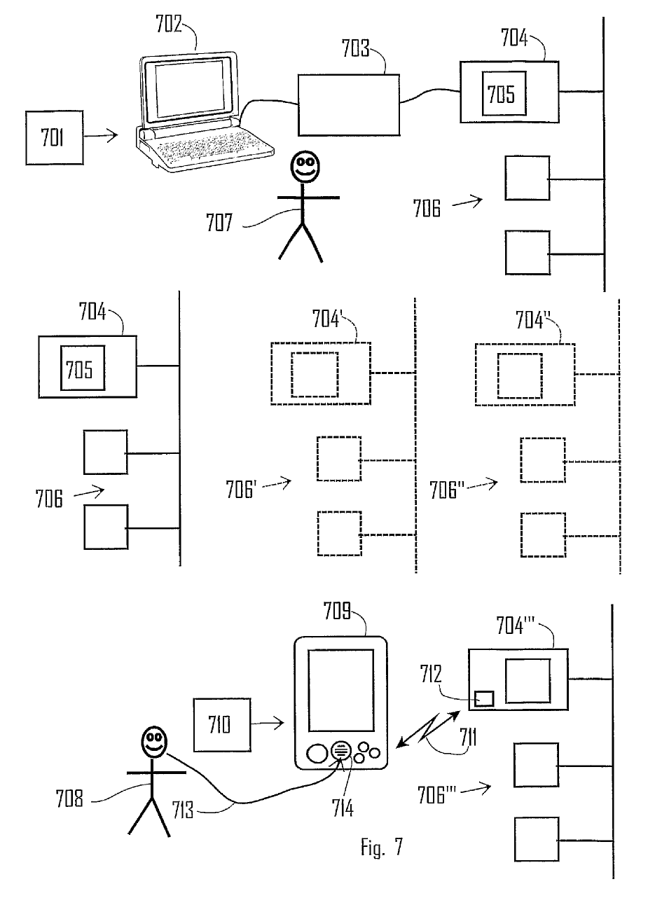

FIG. 7 shows a variant of the utilization of this disclosure. In a first stage, the tool 701 that is implemented on a PC 702, which is connected to a second unit 703 and a third unit 704, is equipped with an extended permanent memory and/or with a memory 705 that can be connected temporarily. The tool arrangement is connected to a system 706 and is connected up for direct analysis of the system, carried out by a human user 707. The user acquires experience of what it is important to check and verify in the system in order to ensure a reliable function. When this experience has been acquired, rules are generated for how the analysis can be repeated automatically in order for a correct diagnosis to be made, for example which messages are to be watched, sequences of messages on both sides of a given message with given content that are to be saved for further analysis, which messages are to be saved upon the appearance of error messages, active transmission of messages in given situations, etc.

These rules can be saved in the form of a data file that can be downloaded to the third unit 704. In addition, the user draws up rules for a partial database adapted for the PDA and rules for how collected information and the analysis result are to be presented in a PDA. These rules are compiled in one or several files that can be interpreted by a PDA with suitable software. These files can also be downloaded to the third unit. In this first stage, the third unit 704 serves as an interface between the system and the other parts of the tool.

In a second stage, the generated files are downloaded to one or several third units. This can be carried out directly by serial communication or via a temporary memory. Using instructions from these files, the third unit can then independently collect and process information that is important for the analysis and save this information in the extended memory. A large number of third units can thus be connected to an equally large number of systems, for example a fleet of vehicles, in a simple way. In this second stage, the third units function as complex data logs.

In a third stage, a technician 708 with a PDA 709 can connect this to a third unit 704′″ that works for a period of time in the system 706′″. The PDA's software 710 starts by uploading, via a Bluetooth connection 711, the files that are stored in the third unit equipped with a Bluetooth interface 712, which files contain information about how the analysis is to be presented in the PDA, how the database is to be organized and how the continued analysis is to be carried out. In this way, a large number of technicians can analyze and diagnose a large number of systems in a rational way. In this third stage, the third units work together with the respective PDAs as a tailor-made analysis tool.

If a test or diagnosis fails, the technician 708 can, in a fourth stage, contact the user 707 who has expertise concerning the system, via a general means of communication. The user 707 can then utilize the technician 708 and bi-directional data transmission between the module 704′″, the technician's PDA 709 and the tool in the PC 702 in order to analyze why the test or the diagnosis failed. By means of analyses and simulations, he can reach a correct diagnosis, carry out a standardized analysis in order to modify the diagnosis, save it in a databank and distribute it to the technician 708 and all his colleagues.

In many cases, a fault arises for which it is difficult to determine the cause, for example sporadic noises in a car, sporadic vibrations, etc. It can then be expedient to log as much data is possible and let the operator indicate when the fault occurs. This can be carried out in a simple way by the operator generating a signal, for example by pressing a button, which can be detected by the system and generate a marker in the collected data. The subsequent analysis work can then be concentrated on data that was collected around the time of the appearance of the marker. A more complex method is for the system to introduce one or several channels for recording signals from a commentator system, whereby the operator can supply voice, image and push-button information that can be related temporally to other recorded data. When the problem occurs, the operator utters, for example, a voice message 713 which is recorded by the microphone 714 in the unit 709. The unit 709 sends a signal 715 via the connection 711 which is recorded and time-stamped as a voice event in the unit 704′″. The message saved in 709 can thus be related at a later stage to data collected in the unit 704′″.

As an alternative to saving the message in 709, it can be transferred directly via the Bluetooth connection 711 and saved in the unit 704′″. Bluetooth is a suitable protocol for the purpose as it was developed especially to facilitate digital sound transmission in realtime.

In many cases, a fault arises for which it is difficult to determine the cause, for example sporadic noises in a car, sporadic vibrations, etc. It can then be expedient to log as much data is possible and let the operator indicate when the fault occurs. This can be carried out in a simple way by the operator generating a signal, for example by pressing a button, which can be detected by the system and generate a marker in the collected data. The subsequent analysis work can then be concentrated on data that was collected around the time of the appearance of the marker.

A more complex method is for the system to introduce a channel for voice-recording that can be related temporally to other recorded data. When the problem occurs, the operator utters a voice message 713 which is recorded by the microphone 714 in the unit 709. The unit 709 sends a signal 715 via the connection 711 which is recorded and time-stamped as a voice event in the unit 704′″. The message saved in 709 can thus be related at a later stage to data collected in the unit 704′″. As an alternative to saving the message in 709, it can be transferred directly via the Bluetooth connection 711 and saved in the unit 704′″. Bluetooth is a suitable protocol for the purpose as it was developed especially to facilitate digital sound transmission in realtime.

A summary of a system constructed according to the concept of this disclosure can, among other things, be considered to comprise a number of units developed for special tasks for analysis and measurements of various kinds in a distributed control system that are connected to a measurement, diagnosis and/or analysis system, called here an M-system, via connections and a common basic protocol. The M-system can work simultaneously with one or several target systems, which communicate using the same or different protocols. A target system is connected to the M-system by a first unit, specially developed for its task in the target system and equipped with a microprocessor, for example a unit for measuring physical data in a unit connected to the target system, a unit for traffic analysis on the bus, a unit for simultaneous measurement of signal levels on two buses. This is connected to a coordination unit with a microprocessor via connections and communicates using a common protocol, for example USB.

USB is suitable for the purpose as the Start of Frame signal is accessible to a microprocessor and well-defined in time, which is a good basis for developing synchronized clocks within the system. In addition, there are various communication modes, some with good synchronization, which are also a good basis for complex detailed solutions with stringent real-time requirements. In addition, USB was originally developed for the transmission of sound and image, which is useful when adding additional information from a human operator to collected data. In addition, much standard equipment is developed with USB connections, such as computers, PDAs, cameras, telephones, memories, etc, that can be integrated into the M-system as required in a simple way. By constructing the system from independent units that communicate using a common protocol, compact efficient units can be easily created with a small development effort by incorporating various unenclosed modules in one and the same housing and letting them communicate via short internal connections.

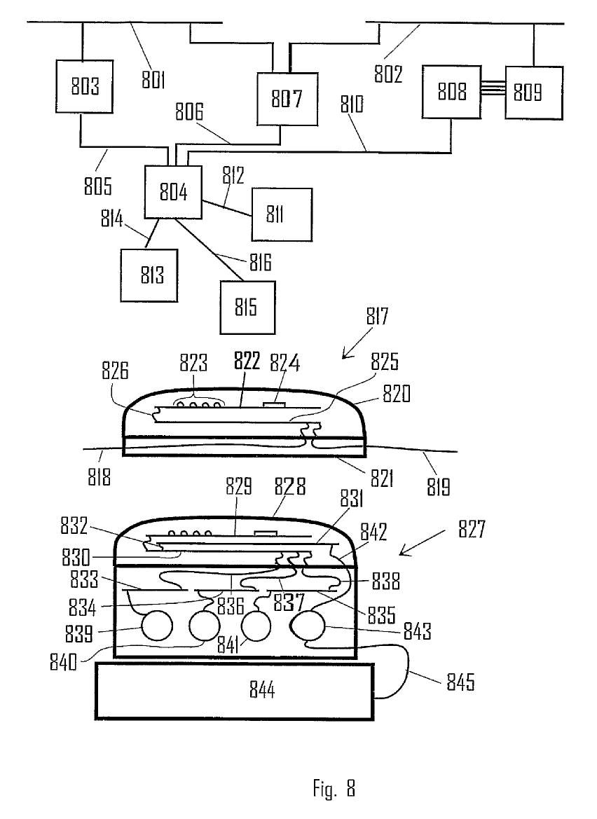

FIG. 8 shows the basic construction of an M-system. Two systems 801, for example a MOST system, and 802, for example a CAN system, in a vehicle are to be analyzed. A module 803 is connected to 80 1, which module 803 was developed for MOST and is connected to the coordination unit 804 via the USB connection 805.

The coordination unit 804 is connected by the USB connection 806 to the unit 807 which is designed to be able to be connected to and analyze the traffic simultaneously on the MOST system 801 and the CAN system 802. The unit 808 is a measurement module that measures the device 809 that is connected to the CAN system 802 and to the coordination unit 804 by the USB connection 8 10. The coordination unit is in turn connected to the memory 811 via the USB connection 812 and to the computer unit 813 via the USB connection 814 and to the camera unit 815 via the USB connection 816.

It can easily be seen that many other combinations can be achieved, particularly with standard units with USB connections, such as headsets, analogue and digital I/O, keyboards, mice, etc. It can also be seen that variants for other commonly-used standards can be incorporated, for example AC97 units for sound units.

Module 817 shows a module for connection to a target system via 8 and to a coordination unit or directly to a computer or PDA via the USB connection 819. The module consists of a casing divided into two, with the upper part 820 and the lower part 821 made of metal or plastic, and the circuit board 822 with the light-emitting diodes 823 and the microprocessor 824 for controlling these on command from the analysis card 825 via the serial connection 826. A considerable cause of variation is how the external connections 825 and 826 are carried out. In the example, the connections are carried out via cable and the unit 817 can be made small. If the external connections are carried out via connectors, more space is required. If such modifications are carried out completely in the lower part 821, a new and taller lower part can be constructed in a simple way, while the upper part 820 remains unchanged. This can then be manufactured with a complex design using an expensive tool.

Variants can then have the same visual appearance and the lower part of the variants can be designed by designers who do not have extensive knowledge of the electronics. An example of a composite unit is shown by 827. The upper part 828 comprises a display card with light-emitting diodes 829 that is connected to a coordination card 830. This is connected to a CPU card for complex data processing 831 via the USB connection 832 and to three different types of analysis card 833,834 and 835 via the USB connections 836,837 and 838. The respective analysis cards are connected to the connectors 839,840 or 841 in accordance with the requirements of the target system of the respective analysis card. The CPU card 831 has a USB connection which is connected to the connector 843 via the cable 842. A hard disk 844 with USB connection is connected to the CPU card via the cable 845 and the connector 843.

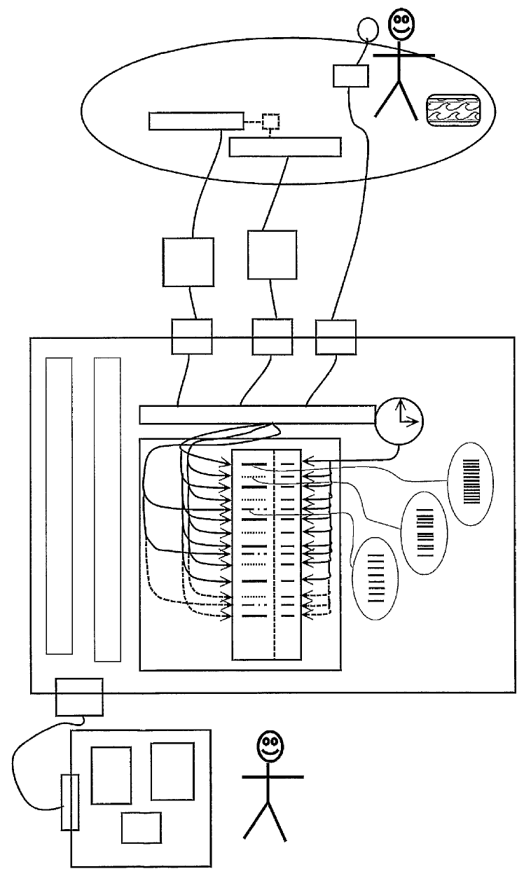

FIG. 9 shows a vehicle 900 with two distributed systems 901,902 and an operator 903. This can, in principle, correspond to a complex sensor that can detect the characteristics and behavior of the car in various situations, both foreseen and unforeseen. The operator can provide his information by voice which is recorded by a microphone 904. The voice information is symbolized by 905 and the digital signals by 906. The systems 901 and 902 can be connected together in a known way via connecting devices and can send digital signals 908 and 909 respectively to the conversion units 910,911 (c.f. the above).

The voice information 905 is converted by means of a conversion unit 912. The signals 906, 908, and 909 are received by a logger 913 that is provided with connection and receiving devices 914,915 and 916 respectively for this purpose. The connections are symbolized by 917, 918, and 919 respectively. The digital signals 906 from the conversion unit 912 can be detected by a coordination unit 920 incorporated in the logger 913 together with the signals 908 and 909 from the two distributed networks 901,902. Each message from each of three units 910, 911, 912, is time-stamped and origin-marked and is stored in a memory unit 921 incorporated in the logger, individually or in groups.

A comparison unit, for example 922, can later read the memory content, separate and reorganize the information in this in various ways and relate the different parts of the divided and reorganized information to each other using the allocated time stamps and origin markers. The logger 913 can be provided with a display unit 924 and/or can be connected to an external display unit 925 or a computer unit via connection and transmission devices 926 and the connection 927 and reception device 928 in the unit 925. Sound and image information can be replayed to an operator 923 using the sound and image card 929 in the computer 925.

In addition to noises, faults, etc, in many situations it is also possible to receive messages from the operator 903 concerning what maneuvers he is carrying out and whether he perceives the behavior of the vehicle as correct or incorrect, for example on a scale of 1 to 10. The operators can be the same person. The operator 903 (or 923) can also be the driver of the vehicle. A clock or clock function is shown by 930. A first information section 932 from the system 901, a second information section 933 from the system 902 and a third information section 934 from the voice and/or image function and/or a coding and/or marking function 904 are stored in a memory 931 comprised in the memory unit (and peripherals). The microphone can be comprised in a PDA, can include or be replaced by a camera, can include or be replaced by a touch-sensitive indicator, etc, and can include or be replaced by a manually- operated device 935, for example a pushbutton and/or code transmitter 936. The symbol 937 symbolizes a fault or driving situation that is to be included in the recording or the comparison. The display device 925 comprises a computer unit and a comparison unit 939.

The operator 923 can constitute or be comprised in the comparison function. The section 934 can comprise a long signal sequence that describes a situation or fault, or a short signal sequence that contains marking, coding, etc. The section can affect or be made to be compared with one or several sections 932, 933, etc, which can coincide or differ in time from the section or the marker 933. In an embodiment, the coordination unit 920 and the memory unit, together with software (set-up) adapted for these units, form a module that is comprised in a second unit (for example a logger) or in a system, where the module can consist of a complex unit that represents advanced development and functionality and in this way facilitates the construction or compiling of the second unit or the system. The invention can also be utilized for fine- tuning of vehicles (cars, motorcycles, boats, etc) for example in connection with racing and development work. While driving, the driver can provide voice, image and/or touch messages regarding driving situations or behavior situations that are recorded in the logger for later use, etc.

In an embodiment, the operator/driver 903 can obtain information from the system 910,911, 913 if error or fault files appear from the system 901 and/or 902 and he/she does not obtain the fault indication in another way. The error files can initiate sound, image, etc.

Thus, for example, a sound indicator 940 can be arranged within the hearing of the operator/driver who, upon the occurrence of such a noise, image and/or vibration signal 940a, can repeat the situation/fault in question in order to analyze the source of the fault or the source of the driving situation. Alternatively or in addition, the cause of the fault or the cause of the driving situation can bring about an indication to the headset 941 of the person 903. A signal 943 in the connection 917 can be conveyed to the operator/driver via the unit 912 and a transmission connection 942.

The concept of this disclosure is not restricted to the embodiments shown above as examples, but can be modified within the framework of the following patent claims and inventive concept disclosed herein.

What is claimed as new and desired to be protected by Letters Patent of the United States is:

1. A logging unit suitable for connection to an arrangement for analysis of a machine comprising a distributed system that emits first digital signals responsive to operating or fault situations in the machine, the logging unit comprising:
a first connection device connected to the distributed system via a first transmission channel;
a second connection device connected to one or more commentator systems via either the first transmission channel or one or more second transmission channels;
a first reception device that receives the first digital signals via the first connection device;
a second reception device that receives second digital signals generated by respective ones of the one or more commentator systems;
a processing unit operatively connected to the first and second reception devices; and a coordinating device that coordinates the first and second digital signals and supplies at least portions of the first and second digital signals to the processing unit,
wherein the processing unit is arranged to compare information content produced by the distributed system during a relevant period of the first digital signals with information content related to an operating or fault situation of the machine produced by the commentator system.

2. The logging unit of claim 1, wherein the commentator system comprises a voice generator.

3. The logging unit of claim 1, wherein the commentator system comprises an image generator.

4. The logging unit of claim 1, wherein the commentator system comprises a voice generator and an image generator.

5. The logging unit of claim 1, wherein the machine comprises a vehicle.

6. The logging unit of claim 1, wherein the coordination device provides two corresponding sections of the first and second digital signals that relate to a fault function in the machine,
wherein the fault function relates to an audible and/or visible fault effect and wherein a selected portion of the first digital signals is supplemented by a voice and/or image-generated portion of the second digital signals.

7. The logging unit of claim 6, wherein, the audible and/or visible fault effect relates to at least one of an engine noise and a gearbox fault.

8. The logging unit of claim 1, wherein the processing unit further comprises a display unit.

9. The logging unit of claim 1, further comprising transmission devices arranged to provide sections of the first and second digital signals to the processing unit via a third connector through a third transmission channel.

10. The logging unit of claim 1, wherein the coordination device provides sections of the first and second digital signals in parallel to one or more of a display and the processing unit.

11. The logging unit of claim 1, wherein the coordination device provides sections of the first and second signals in a form suitable for use by a data analyzer.

12. The logging unit of claim 1, wherein the commentator system is allocated to a first category of personnel and the processing unit is allocated to a second category of personnel.

13. An arrangement for analysis of a machine that comprises one or more distributed systems that emit first digital signals relating to operating or fault situations in the machine, the arrangement comprising:
means for extracting a plurality of first digital signals relating to the operating or fault situations from the respective distributed system;
a logging unit arranged to collect the first digital signals via one or several first transmission channels allocated to the first digital signals and arranged between the machine and the logging unit;
one or more commentator systems arranged in association with the machine in order to enable a first operator to add supplementary voice and/or image information about operating and/or fault situations in the machine to information content in the first digital signals;
a conversion device that converts signals from the commentator systems to second digital signals;
means for collecting the second digital signals via one or more second transmission channels; and
means for coordinating the first and second digital signals and providing sections of the first and second digital signals to one or both of a display and a processing unit arranged to compare information content produced by one of the one or more distributed systems during a relevant section of the first digital signals with information content produced by one of the commentator systems concerning an operating or fault situation of the machine during a section of the second digital signals.

14. The arrangement of claim 13, wherein the section of the second digital signals correspond to the relevant section of the first digital signals.

15. The arrangement of claim 13, wherein the section of the second digital signals differs from the relevant section of the first digital signals.

16. The arrangement of claim 13, wherein the coordination device comprises a voice-controlled device compatible with one or more of marking, time, and code indications provided in either of the first and second digital signals.

17. The arrangement of claim 13, wherein the relevant section of the first digital signals and the section of the second digital signals correspond to each other temporally.

18. The arrangement of claim 13, wherein the processor unit processes sections of the second digital signals so as to be able to be compared with sections of the first signals recorded either earlier or later.

19. A device for collecting information emanating from a CAN or MOST distributed system in or on a vehicle, the device comprising:
a connection to a commentator system comprising a recording device suitable for speech or image messages, or both;
a first device connected to the commentator system that converts the speech image messages or both to digital signals,
wherein the digital signals are distributed to a collection unit arranged to incorporate the digital signals together with other signals obtained from the other collected information from the CAN or MOST distributed system.

20. The device of claim 19, wherein signals from the commentator system are related to the other collected information by marking information that indicates subsections of the other collected information associated with subsections in information emanating from the commentator system.

21. The device of claim 20, wherein the marking information is sent as a signal arranged to be initiated upon the initiation of the subsection by the recording device and distributed to the collection device,
wherein the marking information is arranged in connection with the subsection as either time-stamped signal information or a time-stamped voice message.

22. The device of claim 19, wherein the first device comprises a microphone in a PDA, said first device being connected to a coordination unit arranged to provide intermediate storage of a relevant speech message as a voice file and to forward the voice file, on a selected time-related occasion,
wherein a distributed control system is time-synchronized with the coordination unit, wherein the relevant speech message may be identified temporally by a time synchronization between the coordination unit and the distributed control system.

23. The device of claim 19, wherein respective subsections that appear as speech messages are related to interference in the vehicle that appears suddenly or unexpectedly in the form of noises or vibrations occurring in the vehicle.

24. The device of claim 22, wherein the information based on the speech messages and stored in the coordination unit forms a basis for analysis work that may be carried out at a later time.

25. The device of claim 19, wherein the connection between the recording device and the collection device comprises a Bluetooth protocol connection.

26. The device of claim 19, wherein the recording device comprises a camera,
wherein first subsection of the digital signals are related to a speech message and a second subsection of the digital signals is related to an image message.

27. A connection device suitable for use in an information handling system connected to one or more distributed target MOST or CAN systems and provided respectively with one or more buses, the device comprising:
two or more bus connection units connected to the target system and having at least one microprocessor each,
each of said two or more bus connection units being arranged to work with one or more tasks including:
conversion of a protocol utilized on the bus to a common protocol utilized in the information handling system,
encapsulation of messages used in the protocol of the target system in the common protocol,
time-stamping of messages and provision of various filter functions and/or trigger functions;
at least one second unit connected to one of said two or more bus connection units, said second unit comprising:
a coordination unit that coordinates downwards the first units and any additional units and,
wherein in a case with more than one coordination unit, an identical coordination unit having a common time base, and either coordinates upwards with a supervisory computer that is in the target system and that has analysis or diagnostics capacity, or with an intermediate communication unit that transmits to a remote supervisory computer,
a third unit connected to the coordination unit, said third unit comprising an information-providing unit;
connection leads having a length in the range of between 100-500 mm, inclusive at least between the target system and the first and second units; and
wherein a common protocol with messages carried directly or encapsulated in other protocols is used,
wherein the first and second units and the second and third units respectively communicate via the connection leads.

28. The connection device of claim 27, wherein the coordination unit comprises a type that works independently without being connected to a supervisory computer and which is capable of carrying out logging to one or more of a memory, a simulation, or a filter.

29. An arrangement suitable for analysis of a vehicle or machine that comprises one or several distributed systems that emit first digital signals relating to operating or fault situations in the vehicle or the machine, the arrangement comprising:
a plurality of first digital signals relating to the operating or fault situations extracted from a respective distributed system;
a logging unit arranged to collect the first digital signals via one or more first transmission channels allocated to the first digital signals and arranged between the vehicle or machine and the logging unit;
one or more initiation devices arranged in association with the in order to enable a first operator to add an initiation signal related to operating and/or fault situations in the vehicle or machine to information content in the first digital signals;
wherein a respective initiation device comprises a conversion device that converts the initiation to one or more second signals,
wherein the logging unit collects the second signals via a transmission channel that comprise either a part of the first transmission channel one or more second transmission channels; and
a device that coordinates the first and second signals by providing sections of the first digital signals to one or more of a display or a processing unit,
wherein the display and processing unit are arranged to provide an indication for a first actor or a second actor in information content produced by a respective distributed system during comparison of a relevant section of the first digital signals with the second signals.

30. A device for collecting a total quantity of information, or parts thereof, of a considerable size, for example of the order of one or several gigabytes, the device comprising:
a collection unit arranged for connection and reception of operation and/or fault messages received in the form of first digital signals from one or several CAN or MOST distributed systems,
said collection unit being arranged for connection and reception of speech and/or image messages in the form of second signals received from a commentator system and, upon the reception of a signal or signals, said collection unit associates the speech and/or image messages and the operation and/or fault messages.

31. A device for transmission of information in connection with distributed control systems, the device comprising:
means for measuring data transmission, diagnostics and/or analyses via connections and a common basic protocol,
said means being arranged to simultaneously work with one or more target systems which communicate using one or more protocols;
a coordination unit connected to one of the distributed control systems via first module units adapted for the respective distributed control systems and tasks therein,
said coordination unit being adapted for communication with the coordination unit using the common basic protocol,
wherein the coordination unit is arranged to communicate with second units using the common basic protocol.

32. A device for information handling in connection with distributed MOST and CAN control systems, the device comprising:
an arrangement that measures, transmits data, performs diagnostics and analyzes via connections and a common basic protocol is arranged to simultaneously work with one or more target systems that communicate using either the same or a different protocol; a coordination unit connected to the control system via first module units adapted for respective system tasks and for communication with the coordination unit using the common basic protocol,
wherein the coordination unit is arranged to be connected to and communicate with second units using the common basic protocol.

33. The device of claim 32, wherein the coordination unit is constructed of one or more first module units and one or more second units arranged in a common casing.

34. The device of claim 32, wherein the common basic protocol is USB.

35. The device of claim 32, wherein the second units work as independent units that communicate using a common protocol.

36. The device of claim 32, wherein the first and second units comprise unenclosed modules and components that communicate using relatively short internal connections.

37. The device of claim 32, wherein the coordination unit is connected to each of a memory, a computer unit, and a camera unit via connections using a common USB protocol.

38. An arrangement, comprising:
units that handle computer-related information appearing in a distributed control system in connection with collecting, storing, analysis, and simulation of data,
wherein respective units each comprise a first and a second unit part, wherein the first unit parts have a same construction with respect to each other and each of the second unit parts comprise different constructions from each other.

39. The arrangement of claim 38, wherein the first unit parts comprise upper parts in the units and the respective upper parts comprise an upper casing,
wherein first components arranged inside the upper casing comprise a circuit board, a light-emitting diode, a microprocessor, an analysis card, and at least one serial connection.

40. The arrangement of claim 38, wherein the second unit parts are designed as a lower casing, and wherein differences in the second unit parts depend upon the connection or connections of the units to or within the system,
wherein cable connections require less space than connections via connectors and wherein second unit parts with a cable connection have a construction that requires less space than second unit parts having a connection that utilizes connectors.

41. The arrangement of claim 39, wherein the respective upper parts comprise:
a display card with the light- emitting diode,
a coordination card, and
a CPU card for complex data processing via a USB connection and three types of analysis card via USB connections,
said three types of analysis cards being connected to connectors,
said CPU card being connected to a hard disk.

42. The arrangement of claim 38, wherein the upper unit parts comprise a relatively complex design, and wherein the second unit parts are relatively simple and capable of production by personnel who do not have extensive knowledge of any electronics that are arranged in the upper unit parts.
